(19) United States
(12) Patent Application Publication
(10) Pub. No.: US 2022/0293463 A1
(43) Pub. Date: Sep. 15, 2022

(54) METHODS AND SYSTEMS FOR FILLING A GAP

(71) Applicant: ASM IP Holding B.V., Almere (NL)

(72) Inventors: René Henricus Jozef Vervuurt, Leuven (BE); Timothee Blanquart, Oud-Heverlee (BE); Viljami Pore, Helsinki (FI); Giuseppe Alessio Verni, Jodoigne (BE); Qi Xie, Wilsele (BE); Ren-Jie Chang, Leuven (BE); Eric James Shero, Phoenix, AZ (US)

(21) Appl. No.: 17/680,607

(22) Filed: Feb. 25, 2022

Related U.S. Application Data
(60) Provisional application No. 63/155,388, filed on Mar. 2, 2021.
(60) Provisional application No. 63/261,877, filed on Sep. 30, 2021.

(51) Int. Cl. H01L 21/768; H01L 21/02

(52) U.S. Cl. CPC H01L 21/76837; H01L 21/0228; H01L 21/02211

(57) ABSTRACT

Disclosed are methods and systems for filling a gap. An exemplary method comprises providing a substrate to a reaction chamber. The substrate comprises the gap. The method further comprises at least partially filling the gap with a gap filling fluid. The method then comprises subjecting the gap filling fluid to a transformation treatment, thus forming a transformed material in the gap. The methods and systems are useful, for example, in the field of integrated circuit manufacture.

### CROSS-REFERENCE TO RELATED APPLICATIONS

This application claims priority to U.S. Provisional Patent Application Ser. No. 63/261,877 filed Sep. 30, 2021 titled METHODS AND SYSTEMS FOR FILLING A GAP; U.S. Provisional Patent Application Ser. No. 63/155,388 filed Mar. 2, 2021 titled METHODS AND SYSTEMS FOR FORMING A LAYER COMPRISING VANADIUM AND NITROGEN and , the disclosures of which is hereby incorporated by reference in their entirety.

### FIELD OF INVENTION

The present disclosure generally relates to the field of semiconductor processing methods and systems, and to the field integrated circuit manufacture. In particular, methods and systems suitable for filling a gap are disclosed.

### BACKGROUND OF THE DISCLOSURE

The scaling of semiconductor devices, such as, for example, logic devices and memory devices, has led to significant improvements in speed and density of integrated circuits. However, conventional device scaling techniques face significant challenges for future technology nodes.

For example, one challenge has been finding suitable ways of filling gaps such as recesses, trenches, vias and the like with a material without formation of any gaps or voids.

Any discussion, including discussion of problems and solutions, set forth in this section has been included in this disclosure solely for the purpose of providing a context for the present disclosure. Such discussion should not be taken as an admission that any or all of the information was known at the time the invention was made or otherwise constitutes prior art.

### SUMMARY OF THE DISCLOSURE

This summary may introduce a selection of concepts in a simplified form, which may be described in further detail below. This summary is not intended to necessarily identify key features or essential features of the claimed subject matter, nor is it intended to be used to limit the scope of the claimed subject matter.

Various embodiments of the present disclosure relate to methods of filling a gap, to structures and devices formed using such methods, and to apparatus for performing the methods and/or for forming the structures and/or devices. The layers may be used in a variety of applications. For example, they may be used in the field of integrated circuit manufacture.

Thus described herein is a method for curing a gap filling fluid, the method comprises providing a substrate comprising a gap. The gap is at least partially filled with a gap filling fluid. The gap filling fluid comprises at least one of a metal and a metalloid. The method further comprises exposing the substrate to a transformation reactant. Thus, at least a part of the gap filling fluid is thermally converted into a transformed material.

Further described herein is a method for filling a gap. The method comprises providing a substrate comprising a gap. The method further comprises at least partially filling the gap with a gap filling fluid. The gap filling fluid comprises at least one of a metal and a metalloid. The method further comprises exposing the substrate to a transformation reactant. Thus, at least a part of the gap filling fluid is thermally converted into a transformed material.

Further described herein is a method of filling a gap. The method comprises providing a substrate. The substrate comprises the gap. The method further comprises providing a system. The system comprises a gap filling fluid reaction chamber and a transformation reaction chamber. The method further comprises executing a plurality of super cycles. A super cycle comprises moving the substrate into the gap filling fluid reaction chamber, forming a gap filling fluid in the gap filling fluid reaction chamber, moving the substrate into the transformation reaction chamber, and, subjecting the substrate to a transformation treatment in the transformation reaction chamber. It shall be understood that forming a gap filling fluid in the gap filling fluid reaction chamber results in at least partially filling the gap with a gap filling fluid. The gap filling fluid comprises at least one of a metal and a metalloid. It shall further be understood that subjecting the substrate to the transformation treatment causes at least part of the gap filling fluid to be converted into a transformed material.

In some embodiments, a method as described herein comprises executing a plurality of super cycles. A super cycle comprises the step of at least partially filling the gap with a gap filling fluid, and the step of subjecting the substrate to a transformation reactant.

In some embodiments, the gap filling fluid further comprises a halogen.

In some embodiments, the gap filling fluid comprises a transition metal.

In some embodiments, the transition metal comprises Ti.

In some embodiments, the gap filling fluid comprises a group IVA element.

In some embodiments, the group IVA element comprises germanium.

In some embodiments, the transformation reactant comprises a group IVA element.

In some embodiments, the transformation reactant comprises a silane.

In some embodiments, the transformation reactant comprises a pnictogen.

In some embodiments, the transformation reactant comprises a chalcogen.

In some embodiments, the transformation reactant comprises a noble gas.

In some embodiments, the transformation reactant comprises a reducing agent.

In some embodiments, the metal or metalloid comprised in the gap filling fluid comprises an element selected from W, Ge, Sb, Te, Nb, Ta, V, Ti, Zr, Hf, Rh, Fe, Cr, Mo, Au, Pt, Ag, Ni, Cu, Co, Zn, Al, In, Sn, and Bi.

Further described herein is a system that comprises a reaction chamber. The system further comprises a precursor gas source that in turn comprises at least one of a metal precursor and a metalloid precursor. The system further comprises a deposition reactant gas source that comprises a deposition reactant. The system further comprises a transformation reactant gas source that comprises a transformation reactant. The system further comprises a controller. The controller is configured to control gas flow into the reaction chamber to carry out a method as described herein.

These and other embodiments will become readily apparent to those skilled in the art from the following detailed description of certain embodiments having reference to the attached figures. The invention is not limited to any particular embodiments disclosed.

### BRIEF DESCRIPTION OF THE DRAWING FIGURES

A more complete understanding of the embodiments of the present disclosure may be derived by referring to the detailed description and claims when considered in connection with the following illustrative figures.

FIG. 1 illustrates an embodiment of a method as disclosed herein.

FIG. 2 illustrates an embodiment of a system (200) in accordance with yet additional exemplary embodiments of the disclosure.

FIG. 3 shows another embodiment of a system (300) as described herein in a stylized way.

FIG. 4 shows a stylized representation of a substrate (400) comprising a gap (410).

FIG. 5 shows another embodiment of a method as described herein.

FIG. 6 shows another embodiment of a method as described herein.

It will be appreciated that elements in the figures are illustrated for simplicity and clarity and have not necessarily been drawn to scale. For example, the dimensions of some of the elements in the figures may be exaggerated relative to other elements to help improve understanding of illustrated embodiments of the present disclosure.

### DETAILED DESCRIPTION OF EXEMPLARY EMBODIMENTS

The description of exemplary embodiments of methods, structures, devices and systems provided below is merely exemplary and is intended for purposes of illustration only; the following description is not intended to limit the scope of the disclosure or the claims. Moreover, recitation of multiple embodiments having stated features is not intended to exclude other embodiments having additional features or other embodiments incorporating different combinations of the stated features. For example, various embodiments are set forth as exemplary embodiments and may be recited in the dependent claims. Unless otherwise noted, the exemplary embodiments or components thereof may be combined or may be applied separate from each other.

In this disclosure, “gas” can include material that is a gas at normal temperature and pressure (NTP), a vaporized solid and/or a vaporized liquid, and can be constituted by a single gas or a mixture of gases, depending on the context. A gas other than the process gas, i.e., a gas introduced without passing through a gas distribution assembly, other gas distribution device, or the like, can be used for, e.g., sealing the reaction space, and can include a seal gas, such as a rare gas. In some cases, the term “precursor” can refer to a compound that participates in the chemical reaction that produces another compound, and particularly to a compound that constitutes a film matrix or a main skeleton of a film; the term “reactant” can be used interchangeably with the term precursor.

As used herein, the term “film” and/or “layer” can refer to any continuous or non- continuous structure and material, such as material deposited by the methods disclosed herein. For example, a film and/or layer can include two-dimensional materials, three-dimensional materials, nanoparticles, partial or full molecular layers or partial or full atomic layers or clusters of atoms and/or molecules. A film or layer may partially or wholly consist of a plurality of dispersed atoms on a surface of a substrate and/or embedded in a substrate/and/or embedded in a device manufactured on that substrate. A film or layer may comprise material or a layer with pinholes and/or isolated islands. A film or layer may be at least partially continuous. A film or layer may be patterned, e.g. subdivided, and may be comprised in a plurality of semiconductor devices.

As used herein, a “structure” can be or can include a substrate as described herein. Structures can include one or more layers overlying the substrate, such as one or more layers formed according to a method as described herein. Device portions can be or include structures. A transformed material manufactured by means of a method as described herein can be or can become a part of a structure.

As used herein, the term “gap filling fluid”, also referred to as “flowable gap fill”, may refer to a composition of matter that is liquid, or that can form a liquid, under the conditions under which is formed and which has the capability to form a solid film. A gap filling fluid can be in a flowable state permanently, or at least temporarily, i.e. for a pre-determined amount of time before the gap filling fluid solidifies. It shall be understood that the gap filling fluid used in, or formed during, a method as described herein comprises at least one of a metal and a metalloid. In some embodiments, the gap filling fluid further comprises a halogen. Alternatively, and in some embodiments, the gap filling fluid does not comprise a halogen. It shall be understood that “gap filling fluid” can, in some embodiments, be only temporarily in a flowable state, for example when the “gap filling fluid” is temporarily formed through formation of liquid oligomers from gaseous monomers during a polymerization reaction, and the liquid oligomers continue to polymerize to form a solid polymeric material. For ease of reference, a solid material formed from a gap filling fluid may, in some embodiments, be simply referred to as “gap filling fluid”.

In some embodiments, the gap filling fluid comprises a compound in a liquid phase that undergoes a gelification process.

In some embodiments, the gap filling fluid comprises oligomers that undergo chain growth as gaseous precursor polymerizes. Accordingly, a flowable oligomer-containing gap filling fluid can, in some embodiments, be temporarily formed on the substrate's surface that solidifies as the oligomers undergo chain growth. Thus, a flowable gap filling fluid can be obtained even at temperatures that are lower than the bulk melting point of a converted layer that is formed by means of a method as disclosed herein.

Of course, the presently described methods can also be used at conversion temperatures which exceed the bulk melting point of gap filling fluids formed by means of the presently described methods.

In some embodiments, a gap filling fluid can be formed even at process conditions at which a bulk gap filling fluid would be normally not be expected to exist in a liquid state, e.g. at temperatures above the bulk gap filling fluid's dew point, or at pressures below the bulk gap filling fluid's critical pressure. In such cases, a gap filling fluid can be formed in gaps through surface tension and capillary effects that locally lower the vapor pressure at which liquid and gas are in equilibrium. In such cases, the gap filling fluid can, in some embodiments, be solidified by cooling the substrate down.

A gap filling fluid can be formed over the entire substrate surface, both outside gaps and inside gaps comprised in the substrate. When the gap filling fluid is formed both outside of the gaps and inside the gaps, the gap filling fluid can, in some exemplary modes of operation, be drawn into a gap by at least one of capillary forces, surface tension, and gravity.

A method as described herein can comprise forming a material such as a gap filling fluid by means of a cyclic deposition process. The term “cyclic deposition process” or “cyclical deposition process” can refer to a sequential introduction of precursors (and/or reactants) into a reaction chamber to deposit a layer over a substrate. A cyclical deposition process can include cyclically providing a precursor, providing a reactant, and generating a plasma in a reaction chamber. Additionally or alternatively, a cyclical deposition process can include cyclically exposing a substrate to active species generated in a remote plasma.

As used herein, the term “purge” may refer to a procedure in which at least one of flow of a precursor, flow of a reactant, and exposure of a substrate to active species, is temporarily stopped. Suitably, active species can be generated by means of a plasma, for example during formation of a gap filling fluid. A purge can occur between two pulses. A pulse can comprise executing a process step such as exposing a substrate to one or more of precursor, providing reactant, and optionally plasma, for a pre-determined amount of time. A purge then comprises temporarily stopping exposure of the substrate to one or more of precursor, reactant, and optionally plasma. It shall be understood that a purge can be effected either in time or in space, or both. For example in the case of temporal purges, a purge step can be used e.g. in the temporal sequence of providing a first precursor to a reaction chamber, providing a purge gas to the reaction chamber, and providing a second precursor to the reaction chamber, wherein the substrate on which a layer is deposited does not move. For example in the case of spatial purges, a purge step can take the following form: moving a substrate from a first location to which a first precursor is continually supplied, through a purge gas curtain, to a second location to which a second precursor is continually supplied.

As used herein, a “precursor” includes a gas or a material that can become gaseous and that can be represented by a chemical formula that includes an element that may be incorporated in a gap filling fluid or a transformed material during a process as described herein. The terms “precursor” and “reactant” can be used interchangeably, in some embodiments. Alternatively, a reactant can comprise a gaseous species, e.g. a noble gas, that interacts with a precursor without becoming incorporated in a gap filling fluid or a transformed material.

The term “oxygen reactant” can refer to a gas or a material that can become gaseous and that can be represented by a chemical formula that includes oxygen. In some cases, the chemical formula includes oxygen and hydrogen.

The term “nitrogen reactant” can refer to a gas or a material that can become gaseous and that can be represented by a chemical formula that includes nitrogen. In some cases, the chemical formula includes nitrogen and hydrogen.

The term “carbon reactant” can refer to a gas or a material that can become gaseous and that can be represented by a chemical formula that includes carbon. In some cases, the chemical formula includes carbon and hydrogen.

Further, in this disclosure, any two numbers of a variable can constitute a workable range of the variable, and any ranges indicated may include or exclude the endpoints. Additionally, any values of variables indicated may refer to precise values or approximate values and include equivalents, and may refer to average, median, representative, majority, or the like. Further, in this disclosure, the terms “including,” “constituted by” and “having” refer independently to “typically or broadly comprising,” “comprising,” “consisting essentially of,” or “consisting of” in some embodiments.

It shall be understood that a distal portion of a gap refers to a portion of the gap feature that is relatively far removed from a substrate's surface, and that the proximal portion of a gap feature refers to a part of the gap feature that is closer to the substrate's surface compared to the lower/deeper portion of the gap feature.

In this disclosure, any defined meanings do not necessarily exclude ordinary and customary meanings, in some embodiments.

The materials formed according to the present methods can be advantageously used in the field of integrated circuit manufacture.

Described herein is a method for curing a gap filling fluid. The method comprises providing a substrate. A monocrystalline silicon wafer may be a suitable substrate. Other substrates may be suitable well, e.g. monocrystalline germanium wafers, gallium arsenide wafers, quartz, sapphire, glass, steel, aluminum, silicon-on-insulator substrates, plastics, etc.

The substrate comprises a gap that is at least partially filled with a gap filling fluid.

In some embodiments, the substrate comprises a plurality of gaps, e.g. from at least 10 gaps to at most 10¹² gaps; one or more of which, for example all of which, may be at least partially filled with a gap filling fluid.

The gap filling fluid comprises at least one of a metal and a metalloid. In other words, the gap filling fluid can comprise a metal, or the gap filling fluid can comprise a metalloid, or the gap filling fluid can comprise a metal and a metalloid. In some embodiments, the gap filling fluid comprises a plurality of metals, or a plurality of metalloids, or both. The method further comprises exposing the substrate to a transformation reactant. Thus, the gap filling fluid is converted at least partially into a transformed material. Suitable transformed materials include one or more of a metal and a metalloid, for example one or more of a transition metal, a post transition metal, and a metalloid. The transformed material can be an elemental solid, an alloy, or a multi-component material. In some embodiments, the transformed material can comprise a silicide, an alloy comprising a metal or metalloid on the one hand and silicon on the other hand, an oxide, a nitride, a carbide, an oxynitride, an oxycarbide, a carbonitride, or an oxycarbonitride. A transformed material can consist of a single phase. In some embodiments, a transformed material can be multi-phasic, and can comprise various microstructural features such as spheroid inclusions, lamellae, grains, amorphous regions, etc.

It shall be understood that converting the gap filling fluid at least partially into a converted material comprises a thermal process. A thermal process comprises subjecting a substrate to heat energy, without subjecting the substrate to a plasma or active species such as radicals. Thermal processes as such are known in the Art, and include soak anneals, rapid thermal anneals, microwave anneals, and the like. A thermal process can comprise exposing the substrate to a suitable ambient, such as an ambient containing oxygen, or an ambient containing nitrogen, or an ambient containing carbon, or an ambient containing hydrogen, or an ambient containing a noble gas.

Methods as described herein can comprise filling a gap by first forming a gap filling fluid, and then converting the gap filling fluid to form a transformed material. Thus, further described herein is a method for filling a gap. The method comprises providing a substrate. The substrate comprises the gap. The method further comprises at least partially filling the gap with a gap filling fluid. The gap filling fluid comprises at least one of a metal and a metalloid. In other words, the gap filling fluid can comprise a metal, or the gap filling fluid can comprise a metalloid, or the gap filling fluid can comprise a metal and a metalloid. In some embodiments, the gap filling fluid comprises a plurality of metals, or a plurality of metalloids, or both. The method further comprises exposing the substrate to a transformation reactant. Thus, at least a part of the gap filling fluid is thermally converted into a solid material.

In some embodiments, the method comprises a plurality of super cycles, in which case a super cycle comprises the step of at least partially filling the gap with a gap filling fluid, and the step of exposing the substrate to a transformation reactant.

In some embodiments, the gap filling fluid is formed in more than one reaction chamber.

Methods as described herein can comprise filling a gap by first forming a gap filling fluid in a first reaction chamber, and then converting the gap filling fluid to form a transformed material in a second reaction chamber. Thus, further described herein is a method for filling a gap. The method comprises providing a substrate. The substrate comprises the gap. The method further comprises providing a system comprising a gap filling fluid reaction chamber and a transformation reaction chamber. The method comprises executing one or more super cycles, for example a plurality of super cycles. A super cycle comprises moving the substrate into the gap filling fluid reaction chamber. A super cycle further comprises forming a gap filling fluid in the gap filling fluid reaction chamber. Accordingly, the gap is at least partially filled with a gap filling fluid. It shall be understood that the gap filling fluid comprises at least one of a metal and a metalloid. In other words, the gap filling fluid can comprise a metal, or the gap filling fluid can comprise a metalloid, or the gap filling fluid can comprise a metal and a metalloid. A super cycle further comprises moving the substrate into the transformation reaction chamber. A super cycle further comprises exposing the substrate to a transformation treatment in the transformation reaction chamber. Thus, at least a part of the gap filling fluid is converted into a transformed material.

In some embodiments, a method as described herein comprises forming a gap filling fluid. Suitably, forming a gap filling fluid can comprise forming a gap filling fluid from a vapor phase precursor and a vapor phase reactant. Forming the gap filling fluid can comprise a plasma enhanced chemical vapor deposition process, or a thermal chemical vapor deposition process. Forming a gap filling fluid can comprised pulsed gas flow, continuous gas flow, or a regime in which some gasses are pulsed and others are flown continuously.

In some embodiments, forming a gap filling fluid comprises generating a plasma in the reaction chamber. A plasma may be generated continuously, or a plasma may be generated intermittently, i.e. in pulses. Thus, in some embodiments, a plasma is continuously generated in the reaction chamber, the reactant is continuously provided to the reaction chamber, and the precursor is provided to the reaction chamber in a plurality of precursor pulses. Alternatively, and in some embodiments, a plasma is generated in the reaction chamber intermittently, i.e. in pulses, the reactant is provided continuously in the reaction chamber, and the precursor is continuously provided to the reaction chamber. Alternatively, and in some embodiments, a plasma is not generated while forming a gap filling fluid, i.e. the gap filling fluid can be formed thermally.

In some embodiments, the precursor comprises an element that is selected from W, Ge, Sb, Te, Nb, Ta, V, Ti, Zr, Hf, Rh, Fe, Cr, Mo, Au, Pt, Ag, Ni, Cu, Co, Zn, Al, In, Sn, and Bi. Of course, and in some embodiments, the precursor can comprise more than one metals, more than one metalloid, or at least one metal and at least one metalloid, in some embodiments.

In some embodiments, the precursor comprises a ligand that in turn comprises an alkyl-substituted benzene ring. Examples of such precursors include precursors comprising a metal center and one or more methylbenzene ligands, ethylbenzene ligands, or propylbenzene ligands. In some embodiments, the precursor comprises a metal halide, for example a metal fluoride, a metal chloride, a metal bromide, or a metal iodide. An exemplary metal halide is vanadium tetrachloride.

In some embodiments, the precursor comprises an alkyl ligand, such as C1 to C4 alkyl, such as methyl, ethyl, propyl, or butyl.

In some embodiments, the precursor comprises an alkylamine ligand, such as an alkylamine ligand comprising at least one C1 to C4 alkyl.

In some embodiments, the precursor comprises an alkoxy ligand, such as a methoxy, ethoxy, or propoxy ligand.

In some embodiments, the reactant comprises a X—X bond or a H—X bond; with X a halogen.

In some embodiments, the reactant comprises at least one of an elemental halogen and a hydrogen halide. Suitable elemental halogens include F₂, Cl₂, Br₂, and I₂. Suitable hydrogen halides include HF, HCI, HBr, and HI.

When the precursor comprises a halogen, the reactant does not necessarily comprise a halogen. Suitable reactants that do not comprise a halogen include oxygen reactants, nitrogen reactants. Suitable oxygen reactants include O₂, O₃, and H₂O. Suitable nitrogen reactants include NH₃ and N₂H₂.

In some embodiments, forming a gap filling fluid can comprises exposing a convertible layer to a halogen-containing reactant, such as an elemental halogen or a halogen hidride. A convertible layer can comprise an element that is selected from W, Ge, Sb, Te, Nb, Ta, V, Ti, Zr, Hf, Rh, Fe, Cr, Mo, Au, Pt, Ag, Ni, Cu, Co, Zn, Al, In, Sn, and Bi. For example, a transformable layer can comprise an elemental layer, an alloy, an oxide, a nitride, or a carbide.

In some embodiments, exposing a convertible layer to a halogen-containing reactant can comprise thermally exposing a substrate to the halogen-containing reactant.

In some embodiments, exposing a convertible layer to a halogen-containing reactant can comprise generating a plasma. In such embodiments, the substrate can be exposed to a direct plasma, or to active species that are generated in a remote plasma.

In some embodiments, a gap filling fluid as formed during a method as described herein can be formed using at least one of a precursor and reactant that comprises more than one metal or metalloid. Thus, in some embodiments, the precursor comprises two or more metals. Additionally or alternatively, the precursor can comprise two or more metalloids. Or, the precursor can comprise at least one metal and at least one metalloid. In some embodiments, the reactant comprises two or more metals. Additionally or alternatively, the reactant can comprise two or more metalloids. Or, the reactant can comprise at least one metal and at least one metalloid.

A transformation treatment may be carried out after all gap filling fluid has been formed, or gap filling fluid formation steps and transformation treatments can be carried out multiple times in an alternating fashion. Thus, in some embodiments, a method as described herein comprises a plurality of super cycles. A super cycle comprises a step of exposing the substrate to a precursor and to a reactant, and the step of exposing the substrate to a transformation treatment.

A transformation treatment may, in some embodiments, be carried out in the same reaction chamber as the reaction chamber in which the gap filling fluid is formed. Alternatively, and in some embodiments, the gap filling fluid may be formed in a first reaction chamber, and the transformation treatment may be carried out in a second reaction chamber. The first and second reaction chambers may be part of a cluster tool comprising 2 or more, e.g. 2, 4, 8, 16, or 32, reaction chambers.

Various transformation treatments can be employed. All transformation treatments have in common that they alter or improve the properties of a gap filling fluid in one way or another.

In some embodiments, the substrate is exposed to the transformation treatment for a duration of at least 0.1 s to at most 1000 s, or of at least 0.2 s to at most 500 s, or of at least 0.5 s to at most 200 s, or of at least 1.0 s to at most 100 s, or of at least 2 s to at most 50 s, or of at least 5 s to at most 20 s.

The transformation treatment can, in some embodiments, be carried out once after the gap has been filled, or it can be carried out multiple times, i.e. gap filling steps and transformation steps can be carried out alternatingly and cyclically in order to fill a gap with a transformed material. Thus, in some embodiments, a method as described herein comprises a plurality of super cycles. A super cycle comprises a step of at least partially filling a gap comprised in a substrate with a gap filling fluid and a step of exposing the substrate to a transformation treatment. For example, a method as described herein can comprise from at least 2 to at most 5, or from at least 5 to at most 10, or from at least 10 to at most 20, or from at least 20 to at most 50, or from at least 50 to at most 100 super cycles.

In some embodiments, a super cycle can directly follow a previous super cycle, or subsequent super cycles can be separated by an inter super cycle purge. A super cycle comprises forming a gap filling fluid and a transformation treatment. In some embodiments, the step of forming the gap filling fluid and the transformation treatment are executed directly after each other. Alternatively, a purge can be executed between a step of forming a gap filling fluid and a transformation treatment, before a step of forming a gap filling fluid, and/or between a transformation treatment and a subsequent step of forming a gap filling fluid.

The total number of super cycles comprised in a method as described herein depends, inter alia, on the total layer thickness that is desired. In some embodiments, the method comprises from at least 1 super cycle to at most 100 super cycles, or from at least 2 super cycles to at most 80 super cycles, or from at least 3 super cycles to at most 70 super cycles, or from at least 4 super cycles to at most 60 super cycles, or from at least 5 super cycles to at most 50 super cycles, or from at least 10 super cycles to at most 40 super cycles, or from at least 20 super cycles to at most 30 super cycles. In some embodiments, the method comprises at most 100 super cycles, or at most 90 super cycles, or at most 80 super cycles, or at most 70 super cycles, or at most 60 super cycles, or at most 50 super cycles, or at most 40 super cycles, or at most 30 super cycles, or at most 20 super cycles, or at most 10 super cycles, or at most 5 super cycles, or at most 4 super cycles, or at most 3 super cycles, or at most 2 super cycles, or a single super cycle.

A transformation treatment comprises exposing a substrate to a transformation reactant.

In some embodiments, the transformation treatment comprises exposing the substrate to a thermal anneal. Suitable anneals are known in the Art as such, and include spike anneals, rapid thermal anneals (RTA), and soak anneals. A thermal anneal can suitably be performed in a cyclical manner, e.g. after a deposition step in a super cycle. Additionally or alternatively, an anneal can be performed as a post-deposition treatment.

In some embodiments, the transformation treatment comprises exposing the substrate to a transformation reactant selected from one or more of a group IVA element, a pnictogen, a chalcogen, a noble gas, or a reducing agent such as a hydrogen-containing gas, and a noble gas.

In some embodiments, the transformation reactant comprises a group IVA element.

In some embodiments, the transformation reactant comprises a silane. Accordingly, a gap filling fluid comprising a metal and a halogen such as F, Cl, Br, or I can be transformed using the silane.

An exemplary transformation treatment includes exposure of the gap filling fluid to a silicon-containing gas, such as a silane-containing gas, such as SiH₄ or a higher-order silane such as disilane or trisilane. Accordingly, a silicon-containing material such as a silicide can be formed in the gap. The silicon-containing material may be, in some embodiments, polycrystalline, amorphous, or partly amorphous and partly polycrystalline. In some embodiments, the gap filling fluid comprises germanium and fluorine, and the transformed material comprises a silicon-germanium alloy.

In exemplary embodiments, the gap filling fluid comprises germanium fluoride and the transformation reactant comprises a silane such as monosilane. In such embodiments, the transformed material can, in some embodiments, comprise elemental germane.

In exemplary embodiments, the gap filling fluid comprises germanium fluoride and the transformation reactant comprises a silane such as monosilane. In such embodiments, the transformed material can, in some embodiments, comprise a silicon germanium alloy.

In exemplary embodiments, the gap filling fluid comprises titanium fluoride and the transformation reactant comprises a silane such as monosilane. In such embodiments, the transformed material can, in some embodiments, comprise elemental titanium.

In exemplary embodiments, the gap filling fluid comprises titanium fluoride and the transformation reactant comprises a silane such as monosilane. In such embodiments, the transformed material can, in some embodiments, comprise at least one of a titanium silicide and a titanium-silicon alloy.

In exemplary embodiments, the gap filling fluid comprises a transition metal, such as a transition metal selected from Ti, Ta, Nb, Hf, Zr, W, and Mo, and the transformation reactant comprises a silane such as monosilane. In such embodiments, the transformed material can, in some embodiments, comprise an elemental transition metal, such as an elemental transition metal selected from Ti, Ta, Nb, Hf, Zr, W, and Mo.

In exemplary embodiments, the gap filling fluid comprises a transition metal, such as a transition metal selected from Ti, Ta, Nb, Hf, Zr, W, and Mo, and the transformation reactant comprises a silane such as monosilane. In such embodiments, the transformed material can, in some embodiments, comprise one or more of a transition metal—silicon alloy, a transition metal silicide, or another transition metal-silicon compound.

In exemplary embodiments, the gap filling fluid comprises a metal chloride, a metal bromide, or a metal iodide and the transformation reactant comprises a phenyl-substituted silane such as a compound having the general formula Ph-SiH₃, wherein Ph stands for a phenyl group. Thus, a transformed material can be formed. The transformed material can comprise one or more of a metal, a metal-silicon alloy, and a metal silicide.

In exemplary embodiments, the gap filling fluid comprises a metal bromide and the transformation reactant comprises a phenyl-substituted halosilane such as a compound having the general formula Ph-SiHₙXₘ, with n and m being integers from at least 0 to at most 3, wherein the sum of n and m equals 3, wherein X stands for a halogen such as Cl, Br, or I, and wherein Ph stands for a phenyl group. A suitable phenyl-substituted halosilane includes Ph-SiHCl₂. Thus, a transformed material can be formed. The transformed material can comprise one or more of a metal, a metal-hydrogen alloy, and a metal hydride.

In some embodiments, the transformation reactant comprises a pnictogen.

In some embodiments, the transformation reactant comprises nitrogen. For example, the transformation reactant can comprise NH₃. Other suitable nitrogen reactants include N₂ and N₂H₂, and gas mixtures comprising N₂ and H₂. Ammonia can be particularly useful for transforming a gap filling fluid comprising vanadium oxide into a vanadium and nitrogen-containing transformed material. A vanadium oxide gap filling fluid can be formed, for example, by employing a vanadium halide precursor, e.g. VCl₄, and an oxygen reactant, e.g. H₂O. Exposing the substrate to a nitridation agent such as a nitrogen-containing gas can result in formation of a nitride in a gap comprised in the substrate.

In some embodiments, a nitrogen-containing reactant can be employed to transform a germanium and fluorine-containing gap filling fluid into germanium nitride.

In some embodiments, a nitrogen-containing reactant can be employed to transform a titanium and fluorine-containing gap filling fluid into a titanium nitride.

In some embodiments, the transformation reactant comprises a chalcogen. Oxygen is a suitable chalcogen. Thus, in some embodiments, the transformation reactant comprises oxygen. Exposing the substrate to an oxygen-containing transformation reactant during the transformation treatment can result in formation of an oxide in a gap comprised in the substrate. For example, this can occur through oxidation of a metal and halogen-containing gap filling fluid. Suitable oxidizing agents include O₂, H₂O, H₂O₂, and N₂O. In some embodiments, the oxygen reactant comprises O₂ and H₂. In some embodiments, the oxygen reactant can be provided together with a noble gas such as He, Ne, Ar, Xe and Kr.

In some embodiments, an oxygen-containing reactant can be employed to transform a germanium and fluorine-containing gap filling fluid into germanium oxide.

In some embodiments, an oxygen-containing reactant can be employed to transform a titanium and fluorine-containing gap filling fluid into a titanium oxide.

In some embodiments, the transformation reactant comprises a noble gas. Suitable noble gasses include He, Ne, Ar, Xe, and Kr. In some embodiments, the transformation reactant consists of, or substantially consists of, one or more noble gasses, for example when the transformation treatment consists of a thermal anneal in a substantially inert atmosphere. Alternatively, a noble gas can be employed in a mixture with another transformation reactant.

In some embodiments, the transformation reactant comprises a reducing agent. In some embodiments, the transformation reactant comprises H₂. In some embodiments, the transformation reactant substantially consists of a noble gas and H₂.

In some embodiments, exposing the substrate to a reducing agent or to a noble gas during the transformation treatment can result in formation of a metallic substance in the gap comprised in the substrate. For example, this can occur through volatilization of the halogens contained in the metal and halogen-containing gap filling fluid. For example, a transformation treatment comprising a thermal anneal and exposing the substrate to a noble gas can result in volatilization of halogens comprised in the gap filling fluid, thereby resulting in formation of a metallic substance in the gap. Suitable noble gasses include He, Ne, Ar, Xe, and Kr. Suitable reducing atmospheres include H₂.

In some embodiments, a transformation treatment comprises exposing the substrate to a reduction step and to an oxidation step. In some embodiments, the reduction step precedes the oxidation step. Alternatively, the oxidation step can precede the reduction step. In some embodiments, the reduction step comprises exposing the substrate to a hydrogen anneal, i.e. to an anneal in a hydrogen-containing atmosphere. In some embodiments, the oxidation step comprises exposing the substrate to an oxygen anneal, i.e. to an anneal in an oxygen-containing atmosphere.

In some embodiments, transforming the gap filling fluid comprises exposing the substrate to a reduction step and to a nitridation step. It shall be understood that a nitridation step refers to a step of converting a material into a nitride, or into a nitrogen-containing alloy. In some embodiments, the reduction step precedes the nitridation step. Alternatively, the nitridation step can precede the reduction step. In some embodiments, the reduction step comprises exposing the substrate to a reduction reactant such as a hydrogen-containing gas. In some embodiments, the nitridation step comprises exposing the substrate to a nitrogen reactant. Suitable nitrogen reactants include gasses comprising at least one of N₂, NH₃, and N₂H₂.

In some embodiments, the substrate is maintained at a temperature of at least −25° C. to at most 600° C., or at a temperature of at least 0° C. to at most 400° C., or at a temperature of at least 0° C. to at most 200° C., or at a temperature of at least 25° C. to at most 150° C., or at a temperature of at least 50° C. to at most 100° C. during at least one of forming a gap filling fluid and during the transformation treatment. It shall be understood that a suitable process temperature can be selected based on the vapor pressure of the gap filling fluid as a function of temperature. Suitable temperatures are those at which a gap filling fluid is in a liquid state, at least temporarily, during formation or after it has formed. For example, when the gap filling fluid comprises titanium fluoride, the substrate can be suitably maintained at a temperature below 100° C. during formation of the gap filling fluid and during at least an initial stage of the transformation treatment.

In some embodiments, and while the gap filling fluid is transformed into a transformed material, the substrate is maintained at a temperature of less than 800° C., or of at least −25° C. to at most 800° C., or of at least 0° C. to at most 700° C., or of at least 25° C. to at most 600° C., or of at least 50° C. to at most 400° C., or of at least 75° C. to at most 200° C., or of at least 100° C. to at most 150° C. In some embodiments, the temperature at which the substrate is maintained while the gap filling fluid is formed equals the temperature at which the substrate is maintained while the gap filling fluid is transformed into a transformed material.

In some embodiments, the presently described methods are carried out at a pressure of less than 760 Torr or of at least 0.2 Torr to at most 760 Torr, of at least 1 Torr to at most 100 Torr, or of at least 1 Torr to at most 10 Torr. In some embodiments, the convertible layer is deposited at a pressure of at most 10.0 Torr, or at a pressure of at most 5.0 Torr, or at a pressure of at most 3.0 Torr, or at a pressure of at most 2.0 Torr, or at a pressure of at most 1.0 Torr, or at a pressure of at most 0.1 Torr, or at a pressure of at least 0.2 Torr to at most 5 Torr, or at a pressure of at least 0.5 Torr to at most 2.0 Torr.

In some embodiments, the metal or metalloid comprised in the gap filling fluid comprises an element selected from W, Ge, Sb, Te, Nb, Ta, V, Ti, Zr, Hf, Rh, Fe, Cr, Mo, Au, Pt, Ag, Ni, Cu, Co, Zn, Al, In, Sn, and Bi. In some embodiments, the gap filling fluid further comprises a halogen. Suitable halogens include F, Cl, Br, and I.

In some embodiments, the gap filling fluid comprises a metalloid. For example, the gap filling fluid can comprise one or more of Ge, Sb, and Te.

In some embodiments, the gap filling fluid comprises a group IVA element. In some embodiments, the group IVA element comprises germanium.

In some embodiments, the gap filling fluid comprises a transition metal. In some embodiments, the transition metal comprises Ti.

In some embodiments, the gap filling fluid comprises an element selected from Ge, Sb, and Te. Thus, converted materials comprising an element selected from Ge, Sb, and Te can be formed.

In some embodiments, forming a gap filling fluid comprising an element selected from Ge, Sb, and Te can comprise utilizing a precursor that comprises an element selected from Ge, Sb, and Te.

Suitably, when the precursor comprises Ge, the reactant can contain a fluorine-containing gas or vapor. Thus, a gap filling fluid comprising at least one of GeF₂ and GeF₄ can be formed.

Suitably, when the precursor comprises Sb, the reactant can contain a fluorine-containing gas or vapor. Thus, a gap filling fluid comprising at least one of SbF₃ and SbF₅ can be formed.

Suitably, when the precursor comprises Te, the reactant can contain a bromine- containing gas or vapor. Thus, a gap filling fluid comprising Te₂Br can be formed.

In some embodiments, the gap filling fluid comprises an element selected from Nb, Ta, V, Ti, Zr, and Hf. Thus, converted materials comprising an element selected from Nb, Ta, V, Ti, Zr, and Hf can be formed.

In some embodiments, forming a gap filling fluid comprising an element selected from Nb, Ta, V, Ti, Zr, and Hf can comprise utilizing a precursor that comprises an element selected from Nb, Ta, V, Ti, Zr, and Hf.

In some embodiments, the precursor can comprise niobium (Nb). In such embodiments, the reactant can suitably comprise at least one of chlorine and iodine. Accordingly, a gap filling fluid comprising at least one of NbCl₄ and NbI₅ can be formed.

In some embodiments, the precursor can comprise tantalum (Ta). In such embodiments, the reactant can suitably comprise one of fluorine, chlorine, bromine, and iodine. Accordingly, a gap filling fluid comprising at least one of TaCl₅, TaI₅, TaF₅, and TaBr₅ can be formed.

In some embodiments, the precursor can comprise vanadium (V). In such embodiments, the reactant can suitably comprise one of fluorine and bromine. Accordingly, a gap filling fluid comprising at least one of VF₄, VF₅, VBr₃ can be formed.

In some embodiments, the precursor can comprise V, the reactant comprises O, and at least one of the precursor and the reactant comprises a halogen, such as F or Cl. Accordingly, a gap filling fluid containing vanadium, oxygen, and a halogen can be obtained. Examples of such gap filling fluids include VOCl₂, V₂O₂F₄, VOCl₃, and VOF₃.

In some embodiments, the precursor can comprise titanium (Ti). In such embodiments, the reactant can suitably comprise fluorine. Accordingly, a gap filling fluid comprising TiF₄ can be formed.

In some embodiments, the precursor can comprise zirconium (Zr). In such embodiments, the reactant can suitably comprise one of chlorine, bromine, and iodine. Accordingly, a gap filling fluid comprising at least one of ZrI₄, ZrCl₄, and ZrBr₄ can be formed.

In some embodiments, the precursor can comprise Zr, the reactant comprises a H and O gas mixture or compound, e.g. H₂O, and at least one of the precursor and the reactant comprises a halogen, such as F. In such embodiments, a gap filling fluid containing ZrF6(H20)2 can be used.

In some embodiments, the precursor can comprise hafnium (Hf). In such embodiments, the reactant can suitably comprise one of chlorine and iodine. Accordingly, a gap filling fluid comprising at least one of HfCl₄ and HfI₄ can be used.

In some embodiments, the gap filling fluid comprises an element selected from Rh, Fe, Cr, and Mo. Thus, converted materials comprising an element selected from Rh, Fe, Cr, and Mo can be formed.

In some embodiments, forming a gap filling fluid comprising an element selected from Rh, Fe, Cr, and Mo can comprise utilizing a precursor that comprises an element selected Rh, Fe, Cr, and Mo.

In some embodiments, the precursor can comprise rhodium (Rh). In such embodiments, the reactant can suitably comprise bromine. Accordingly, a gap filling fluid comprising RhBr₃ can be formed.

In some embodiments, the precursor can comprise iron (Fe). In such embodiments, the reactant can suitably comprise bromine. Accordingly, a gap filling fluid comprising at least one of FeBr₃ and FeBr₂ can be formed.

In some embodiments, the precursor can comprise chromium (Cr). In such embodiments, the reactant can suitably comprise fluorine. Accordingly, a gap filling fluid comprising CrF₅ can be formed.

In some embodiments, the precursor can comprise molybdenum (Mo). In such embodiments, the reactant can suitably comprise chlorine, bromine, or iodine. Accordingly, a gap filling fluid comprising at least one of Mo₆Cl₁₂, MoCl₄, MoI₃, and MoBr₃ can be formed.

In some embodiments, the gap filling fluid comprises an element selected from Au, Ag, Pt, Ni, Cu, Co, and Zn. Thus, converted materials comprising an element selected from Au, Ag, Pt, Ni, Cu, Co, and Zn can be formed.

In some embodiments, forming a gap filling fluid comprising an element selected from Au, Ag, Pt, Ni, Cu, Co, and Zn can comprise utilizing a precursor that comprises an element selected Au, Ag, Pt, Ni, Cu, Co, and Zn.

In some embodiments, the precursor comprises gold (Au). In such embodiments, the reactant can suitably comprise fluorine or bromine. Accordingly, a gap filling fluid comprising at least one of AuF₃ and AuBr can be formed.

In some embodiments, the precursor comprises silver (Ag). In such embodiments, the reactant can suitably comprise fluorine. Accordingly, a gap filling fluid comprising AgF₃ can be formed.

In some embodiments, the precursor comprises platinum (Pt). In such embodiments, the reactant can suitably comprise bromine. Accordingly, a gap filling fluid comprising PtBr₄ can be formed.

In some embodiments, the precursor comprises nickel (Ni). In such embodiments, the reactant can suitably comprise bromine. Accordingly, a gap filling fluid comprising NiBr₂ can be formed.

In some embodiments, the precursor comprises copper (Cu). In such embodiments, the reactant can suitably comprise bromine. Accordingly, a gap filling fluid comprising CuBr₂ can be formed.

In some embodiments, the precursor comprises cobalt (Co). In such embodiments, the reactant can suitably comprise iodine. Accordingly, a gap filling fluid comprising Col can be formed.

In some embodiments, the precursor can comprise Co, the reactant comprises a H and O gas mixture or compound, e.g. H₂O, and at least one of the precursor and the reactant comprises a halogen, such as Cl. In such embodiments, a gap filling fluid containing CoCl₂(H₂O)₂ can be formed.

In some embodiments, the precursor comprises zinc (Zn), for example metallic Zn or an inorganic Zn compound. In such embodiments, the reactant can suitably comprise at least one of chlorine and iodine. Accordingly, a gap filling fluid comprising at least one of ZnCl₂ and ZnI₂ can be formed.

In some embodiments, the gap filling fluid comprises an element selected from Al, In, Sn, and Bi. Thus, converted materials comprising an element selected from Al, In, Sn, and Bi can be formed.

In some embodiments, forming a gap filling fluid comprising an element selected from Al, In, Sn, and Bi can comprise utilizing a precursor that comprises an element selected from Al, In, Sn, and Bi.

In some embodiments, the precursor can comprise aluminum (Al). In such embodiments, the reactant can suitably comprise chlorine or iodine. Accordingly, a gap filling fluid comprising at least one of AlCl₃ and AlI₃ can be formed.

In some embodiments, the precursor can comprise indium (In). In such embodiments, the reactant can suitably comprise bromine. Accordingly, a gap filling fluid comprising InBr₃ can be formed.

In some embodiments, the precursor comprises tin (Sn). In such embodiments, the reactant can suitably comprise at least one of chlorine and bromine. Accordingly, a gap filling fluid comprising at least one of SnCl₂ and SnBr₂ can be formed.

In some embodiments, the precursor can comprise bismuth (Bi). In such embodiments, the reactant can suitably comprise fluorine. Accordingly, a gap filling fluid comprising BiF₅ can be formed.

Further described herein is a system. The system comprises a reaction chamber and a precursor gas source. The precursor gas source comprises a precursor. The precursor can comprise a metal precursor, a metalloid precursor, or both. The system further comprises a deposition reactant gas source that comprises a deposition reactant. The system can be used for allowing the deposition reactant and the metalloid precursor to react, thereby forming a gap filling fluid.

The system further comprises a transformation reactant gas source. The transformation reactant gas source comprises a transformation reactant. Additionally or alternatively, the system can comprise one or more gas lines that are or can be arranged to provide the system with a transformation reactant. The system further comprises a controller. The controller is configured to control gas flow into the reaction chamber to carry out a method as described herein.

In some embodiments, the system comprises two distinct, i.e. separate, reaction chambers: a first reaction chamber and a second reaction chamber. The first reaction chamber is constructed and arranged for forming a gap filling fluid on the substrate. The second reaction chamber is constructed and arranged for converting the gap filling fluid into a transformed material. In some embodiments, the first reaction chamber is maintained at a first reaction chamber temperature, and the second reaction chamber is maintained at a second reaction chamber temperature. In some embodiments, the first reaction chamber temperature is lower than the second reaction chamber temperature, for example from at least 10° C. lower to at most 100° C. lower. In some embodiments, the first reaction chamber temperature is higher than the second reaction chamber temperature, for example from at least 10° C. higher to at most 100° C. higher. In some embodiments, the first reaction chamber temperature is equal to the second reaction chamber temperature, e.g. within a margin of 10° C., 20° C., 30° C., or 40° C.

In some embodiments, a method as described herein can be carried out in a system comprising two reaction chambers. Thus, further described herein is a method for filling a gap. The method comprises providing a substrate. The substrate comprises the gap. The method further comprises providing a system that comprises a first reaction chamber and a second reaction chamber. The method further comprises providing a precursor to the first reaction chamber. The method further comprises providing a reactant to the second reaction chamber. The method further comprises executing a plurality of deposition cycles. A deposition cycle comprises moving the substrate to the first reaction chamber, and moving the substrate to the second reaction chamber. It shall be understood that at least one of the precursor and the reactant comprise a metal or a metalloid, and at least one of the precursor and the reactant comprise a halogen. Thus, the precursor and the reactant are allowed to form a gap filling fluid, and the gap is at least partially filled with the gap filling fluid. It shall be understood that the gap filling fluid comprises the metal or metalloid. In some embodiments, the gap filling fluid further comprises the halogen. In some embodiments, the gap filling fluid does not comprise the halogen.

In accordance with yet additional embodiments of the disclosure, a device or portion thereof can be formed using a method and/or a structure as described herein. The device can include a substrate, one or more insulating layers, one or more metallic layers, and one or more semiconducting layers. The device further comprises a gap filled using a method as disclosed herein.

Further described is a field effect transistor comprising a gate contact comprising a layer formed according to a method as described herein.

Further described is a metal contact comprising a layer deposited by means of a method as described herein.

Further provided herein is a metal-insulator-metal (MIM) capacitor comprising an electrode comprising a material formed by means of a method as described herein.

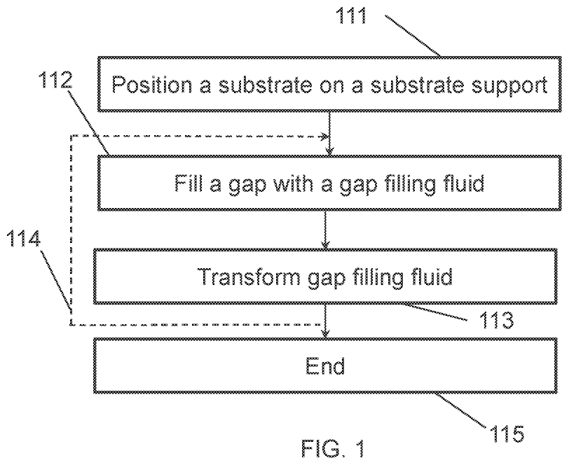

FIG. 1 shows a schematic representation of an embodiment of a method as described herein. The method can be used, for example, in order to form an electrode in a semiconductor device. However, unless otherwise noted, the presently described methods are not limited to such applications. The method comprises a step (111) of positioning a substrate on a substrate support. The substrate support is positioned in a reaction chamber. Suitable substrate supports include pedestals, susceptors, and the like. The method further comprises filling a gap comprised in the substrate (112) with a gap filling fluid. Suitable gap filling fluids and methods of forming them are described elsewhere herein. Optionally, the reaction chamber is then purged.

The method further comprises a step of transforming the gap filling fluid (113) to form a transformed material. In some embodiments, the step of transforming the gap filling fluid (113) to form a transformed material can be carried out in the same reaction chamber as the step of filling the gap comprised in the substrate (112). Alternatively, the step of transforming the gap filling fluid (113) to form a transformed material can be carried out in a different reaction chamber as the reaction chamber in which the step of filling the gap comprised in the substrate (112) is carried out.

Optionally, a purge is carried out after the step of transforming the gap filling fluid (113). When the step of transforming the gap filling fluid (113) to form a transformed material is carried out in the same reaction chamber as the step of filling the gap comprised in the substrate (112), then the purge can comprise temporarily stopping gas flow into the reaction chamber other than purge gas flow, such as flow of a noble gas. When the step of transforming the gap filling fluid (113) to form a transformed material is carried out in a different reaction chamber as the reaction chamber in which the step of filling the gap comprised in the substrate (112) is carried out, then transporting the substrate to the different reaction chamber itself can, in some embodiments, constitute a purge.

The step of transforming the gap filling fluid (113) comprises a thermal transformation process that comprises exposing the substrate to a transformation reactant in a thermal way, that is without simultaneously exposing the substrate to an active species, e.g. a plasma-generated active species. Optionally, the method of FIG. 1 comprises a plurality of super cycles (114) in which the steps of filling the gap with the gap filling fluid (112) and transforming the gap filling fluid (113) are repeated one or more times. After a pre-determined amount of transformed material has been formed on the substrate, the method of FIG. 1 ends (115).

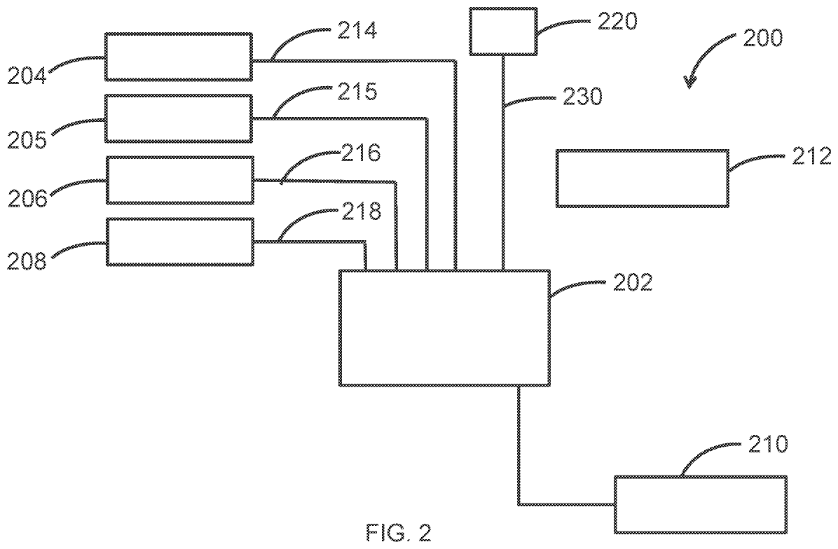

FIG. 2 illustrates a system (200) in accordance with yet additional exemplary embodiments of the disclosure. The system (200) can be used to perform a method as described herein and/or form a structure or device portion, e.g. in an integrated circuit, as described herein.

In the illustrated example, the system (200) includes one or more reaction chambers (202), a precursor gas source (204), a reactant gas source (206), a purge gas source (208), an exhaust (210), and a controller (212).

The reaction chamber (202) can include any suitable reaction chamber, such as an ALD or CVD reaction chamber.

The precursor gas source (204) can include a vessel and one or more precursors as described herein—alone or mixed with one or more carrier (e.g., noble) gases. The reactant gas source (206) can include a vessel and one or more reactants as described herein—alone or mixed with one or more carrier gases. The purge gas source (208) can include one or more inert gases as described herein. Although illustrated with four gas sources (204-208), the system (200) can include any suitable number of gas sources. The gas sources (204-208) can be coupled to reaction chamber (202) via lines (214-218), which can each include flow controllers, valves, heaters, and the like. The exhaust (210) can include one or more vacuum pumps.

The system (200) of FIG. 2 comprises, as illustrated, an optional remote plasma source (220) that is operationally coupled to the reaction chamber (202). It shall be understood that in some embodiments (not illustrated), the remote plasma source can be omitted. The inclusion of a remote plasma source (220) can be advantageous for forming a gap filling fluid, in some embodiments. Suitable remote plasma sources (220) as such are known in the Art, and comprise inductively coupled plasma sources, microwave plasma sources, and capacitive plasma sources. A remote plasma source can be positioned adjacent to the reaction chamber, or the remote plasma source can be positioned at a certain distance from the reaction chamber, e.g. at a distance of at least 1.0 m to at most 10.0 m. When the remote plasma source (220) is positioned at a certain distance from the reaction chamber (202), the remote plasma source (220) can be operationally connected to the reaction chamber (202) via an active species duct (230). The active species duct can comprise a pipe. Optionally, the pipe can contain one or more mesh plates. The mesh plates can at least partially block some reactive species such as ions and electromagnetic radiation while letting other reactive species, e.g. radicals, pass.

Of course, and in some embodiments, other plasmas can be used in addition or as an alternative to the remote plasma, in some embodiments. Suitable additional or alternative plasmas include indirect plasmas and direct plasmas. Thus, and in some embodiments, the reaction chamber comprises a showerhead injector, a substrate support, and a direct plasma source (none of which are shown). In exemplary modes of operation, an RF bias can be applied to the showerhead injector by the direct plasma source, and the substrate support can be grounded. Thus, a substrate can be efficiently exposed to a direct plasma which can be useful, for example, when forming a gap filling fluid, or when exposing a transformed material to a post- transformation plasma treatment.

The controller (212) includes electronic circuitry and software to selectively operate valves, manifolds, heaters, pumps and other components included in the system (200). Such circuitry and components operate to introduce precursors, reactants, and purge gases from the respective sources (204-208). The controller (212) can control timing of gas pulse sequences, temperature of the substrate and/or reaction chamber, pressure within the reaction chamber, and various other operations to provide proper operation of the system (200). The controller (212) can include control software to electrically or pneumatically control valves to control flow of precursors, reactants and purge gases into and out of the reaction chamber (202). The controller (212) can include modules such as a software or hardware component, e.g., a FPGA or ASIC, which performs certain tasks. A module can advantageously be configured to reside on the addressable storage medium of the control system and be configured to execute one or more processes.

Other configurations of the system (200) are possible, including different numbers and kinds of precursor and reactant sources and purge gas sources. Further, it will be appreciated that there are many arrangements of valves, conduits, precursor sources, and purge gas sources that may be used to accomplish the goal of selectively feeding gases into the reaction chamber (202). Further, as a schematic representation of a system, many components have been omitted for simplicity of illustration, and such components may include, for example, various valves, manifolds, purifiers, heaters, containers, vents, and/or bypasses.

During operation of the system (200), substrates, such as semiconductor wafers (not illustrated), are transferred from, e.g., a substrate handling system to reaction chamber (202). Once such substrate(s) are transferred to reaction chamber (202), one or more gases from the gas sources (204-208), such as precursors, reactants, carrier gases, and/or purge gases, are introduced into the reaction chamber (202).

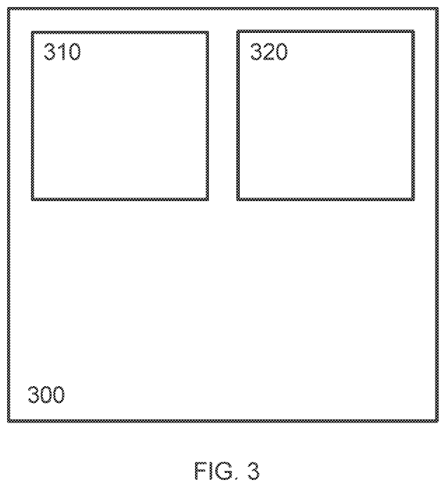

FIG. 3 shows another embodiment of a system (300) as described herein in a stylized way. The system (300) of FIG. 3 is similar to that of FIG. 2. It comprises two distinct reaction chambers: a first reaction chamber (310) and a second reaction chamber (320). The first reaction chamber (310) is arranged for at least partially filling a gap with a gap filling fluid. The second reaction chamber (320) is arranged for transforming the gap filling fluid into a transformed material.

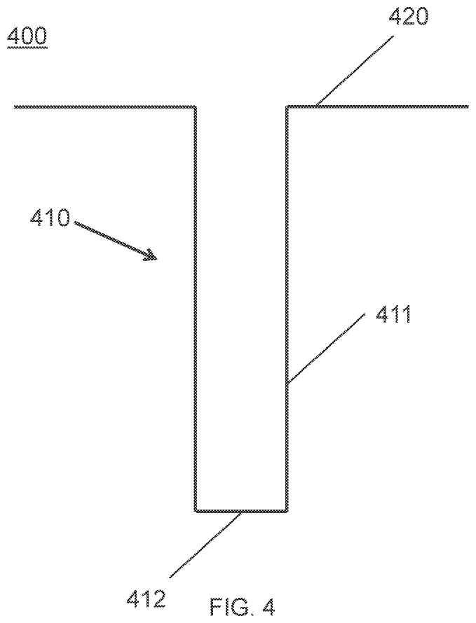

FIG. 4 shows a schematic representation of a substrate (500) comprising a gap (410). The gap (410) comprises a sidewall (411) and a distal end (412). The substrate further comprises a proximal surface (420). In some embodiments, the sidewall (411), the distal end (412) comprise the same material. In some embodiments, at least one of the sidewall (411) and the distal end comprise a dielectric, such as a silicon containing dielectric such as silicon oxide, silicon nitride, silicon carbide, and mixtures thereof. In some embodiments, the dielectric comprises hydrogen. In some embodiments, at least one of the sidewall (411) and the distal end (412) comprise a metal such as a transition metal, a post transition metal, and a rare earth metal. In some embodiments, the metal comprises Cu, Co, W, Ru, Mo, Al, or an alloy thereof. In some embodiments, at least one of the sidewall (411) and the distal end (412)

In some embodiments, the sidewall (411) and the distal end (412) have an identical, or a substantially identical, composition. In some embodiments, the sidewall (411) and the distal end (412) have a different composition. In some embodiments, the sidewall and the distal end (412) comprise a dielectric. In some embodiments, the sidewall (411) and the distal end (412) comprise a metal. In some embodiments, the sidewall (411) comprises a metal and the distal end (412) comprises a dielectric. In some embodiments, the sidewall (411) comprises a dielectric and the distal end comprises a metal.

In some embodiments, the proximal surface (420) has the same composition as the sidewall (411). In some embodiments, the proximal surface (420) has a different composition than the sidewall (411). In some embodiments, the proximal surface (420) has a different composition than the distal end (412). In some embodiments, the proximal surface (420) has the same composition as the distal end (412).

In some embodiments, the proximal surface (420), the sidewall (411), and the distal end (412) comprise the same material. In some embodiments, the proximal surface (420), the sidewall (411), and the distal end (412) comprise a dielectric. In some embodiments, the proximal surface (420), the sidewall (411), and the distal end (412) comprise a metal. In some embodiments, the proximal surface (420), the sidewall (411), and the distal end (412) comprise a semiconductor.

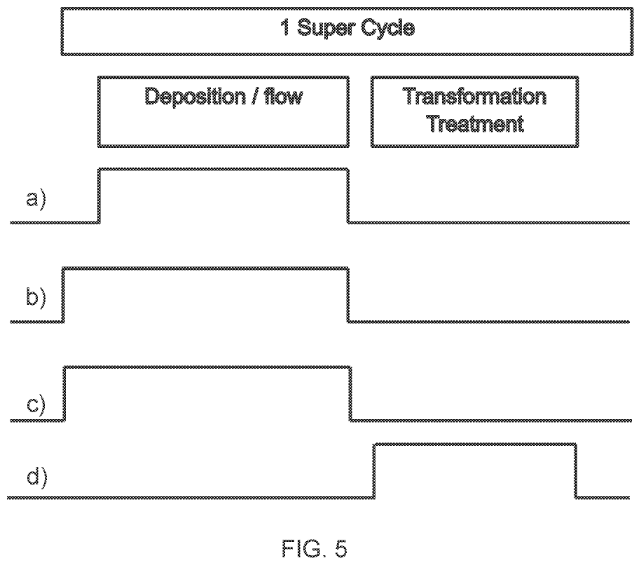

FIG. 5 shows the time evolution of several parameters in embodiments of a method as described herein. This embodiment is carried out in a system comprising a reaction chamber and a remote plasma source. In particular, FIG. 5 shows processes comprising a super cycle.

FIG. 5 line a) denotes a deposition/flow step. During the deposition step, the substrate is exposed to precursor. During the transformation treatment, the substrate is not exposed to precursor. The precursor can be provided to a remote plasma source, or to a reaction space comprising the substrate, or both.

FIG. 5 line b) denotes providing a halogen-containing gas and an ignition gas to a remote plasma source. During the deposition step, the halogen-containing gas and the ignition gas can be provided to the remote plasma source. During the transformation treatment, the flow halogen-containing gas and ignition gas is stopped. In the embodiment shown, the halogen- containing gas and the ignition gas are provided to the remote plasma source even before the deposition step starts.

FIG. 5 line c) denotes providing RF power to the remote plasma source. During the deposition step, RF power is provided to the remote plasma source. Hence, the remote plasma source is on during the deposition step. During the transformation treatment, no RF power is provided to the remote plasma source. In the embodiment shown, RF power is provided to the remote plasma source even before the deposition step starts.

Providing halogen-containing gas, ignition gas, and RF power to the remote plasma source before the deposition step starts, advantageously allows for obtaining a uniform and time-stable gas composition in the remote plasma source before precursor flow starts, and the actual deposition starts.

FIG. 5 line d) denotes exposing the substrate to transformation treatment process gas. Suitable transformation treatment process gasses include noble gasses such as He and Ar, oxygen reactants such as H₂O and O₂, nitrogen reactants such as NH₃, carbon reactants such as CH₄, reducing agents such as H₂, and silicon-containing compounds such as a silane, such as monosilane, disilane, trisilane, etc.

The process of FIG. 5 causes formation of a gap filling fluid in gaps comprised in the substrate during the deposition step. During the transformation treatment, the gap filling fluid is transformed, e.g. through densification, volatilization of some components, reduction, oxidation, nitrification, or carburization.

In some embodiments (not shown), the method can comprise a plurality of super cycles, either one super cycle directly following a previous super cycle, or subsequent super cycles being separated by an inter super cycle purge. A super cycle comprises a deposition step, and a transformation treatment. The deposition step can alternatively be named a deposition/flow step. In some embodiments, the deposition step and the transformation treatment are executed directly after another. Alternatively, a purge can be executed between a deposition step and a transformation treatment, before a deposition step, and/or between a transformation treatment and a subsequent deposition step.

In some embodiments, a purge before a deposition step comprises stopping precursor flow, and stopping exposing the substrate to transformation treatment process gas. During at least part of the purge before a deposition step, halogen-containing gas and an ignition gas and RF power can be provided to the remote plasma source, thereby enhancing process stability.

In some embodiments, a purge between a deposition step and a transformation treatment comprises throttling precursor flow, not exposing the substrate to transformation treatment process gas, not providing halogen-containing gas and an ignition gas to the remote plasma source, and not providing RF power to the remote plasma source.

In some embodiments, a purge after a transformation treatment comprises throttling precursor flow, not exposing the substrate to transformation treatment process gas, not providing halogen-containing gas and an ignition gas to the remote plasma source, and not providing RF power to the remote plasma source.

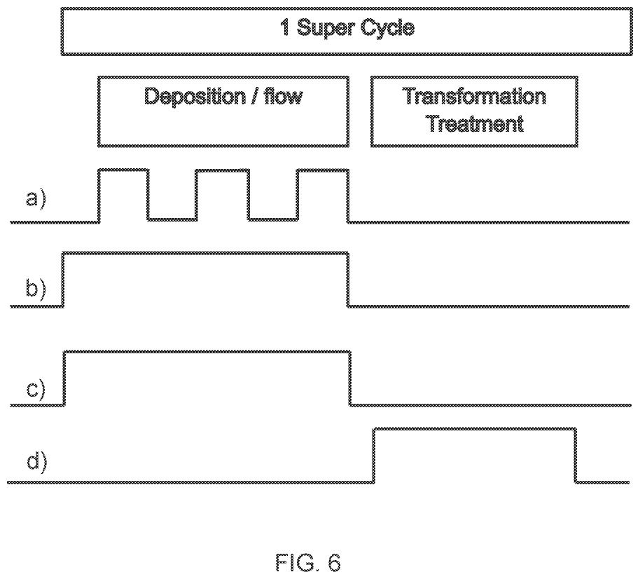

FIG. 6 shows another embodiment of a method as described herein. The method of FIG. 6 is similar to that of FIG. 5, and only the differences are highlighted here.

As in FIG. 5, FIG. 6 line a) denotes precursor flow, FIG. 6, line b) denotes providing a halogen-containing gas and an ignition gas to a remote plasma source, FIG. 6 line c) denotes providing RF power to the remote plasma source, and FIG. 6 line d) denotes exposing the substrate to transformation treatment process gas.

Whereas in the process of FIG. 5, precursor is flown continuously, the process of FIG. 6 features pulsed precursor flow. In other words, in a process according to FIG. 6, precursor can be provided intermittently. In some embodiments, precursor is provided in a plurality of micro pulses. The micropulses can be separated by micro purges. For example, one deposition step can comprise from at least 2 to at most 10⁵ micropulses, or from at least 5 to at most 10⁴ micropulses, or from at least 10 to at least 10³ micropulses, or from at least 20 to at most 100 micropulses. It shall be understood that, as in the process of FIG. 5, a process according to FIG. 6 can comprise providing precursor to a remote plasma source, or to a reaction space comprising the substrate, or both.

1. A method for curing a gap filling fluid, the method comprising
providing a substrate comprising a gap, the gap being at least partially filled with a gap filling fluid, the gap filling fluid comprising at least one of a metal and a metalloid; and
exposing the substrate to a transformation reactant, thereby thermally converting at least a part of the gap filling fluid into a transformed material.

2. The method according claim 1 wherein the gap filling fluid further comprises a halogen.

3. The method according to claim 1 wherein the gap filling fluid comprises a transition metal.

4. The method according to claim 3 wherein the transition metal comprises Ti.

5. The method according to claim 1 wherein the gap filling fluid comprises a group IVA element.

6. The method according to claim 5 wherein the group IVA element comprises germanium.

7. The method according to claim 1 wherein the transformation reactant comprises a group IVA element.

8. The method according to claim 7 wherein the transformation reactant comprises a silane.

9. The method according to claim 1 wherein the transformation reactant comprises a pnictogen.

10. The method according to claim 1 wherein the transformation reactant comprises a chalcogen.

11. The method according to claim 1 wherein the transformation reactant comprises a noble gas.

12. The method according to claim 1 wherein the transformation reactant comprises a reducing agent.

13. The method according to claim 1 wherein the metal or metalloid comprised in the gap filling fluid comprises an element selected from W, Ge, Sb, Te, Nb, Ta, V, Ti, Zr, Hf, Rh, Fe, Cr, Mo, Au, Pt, Ag, Ni, Cu, Co, Zn, Al, In, Sn, and Bi.

14. A system comprising:
a reaction chamber;
a precursor gas source comprising at least one of a metal precursor and a metalloid precursor;
a deposition reactant gas source comprising a deposition reactant;
a transformation reactant gas source comprising a transformation reactant; and,
a controller, wherein the controller is configured to control gas flow into the reaction chamber to carry out a method according to claim 1.

15. A method for filling a gap, the method comprising
providing a substrate comprising a gap;
at least partially filling the gap with a gap filling fluid, the gap filling fluid comprising at least one of a metal and a metalloid; and
exposing the substrate to a transformation reactant, thereby thermally converting at least a part of the gap filling fluid into a transformed material.

16. The method according to claim 15 comprising executing a plurality of super cycles, a super cycle comprising the step of at least partially filling the gap with a gap filling fluid, and the step of subjecting the substrate to a transformation reactant.

17. A method of filling a gap, the method comprising
providing a substrate, the substrate comprising the gap;
providing a system comprising a gap filling fluid reaction chamber and a transformation reaction chamber;
executing a plurality of super cycles, a super cycle comprising
moving the substrate into the gap filling fluid reaction chamber;
forming a gap filling fluid in the gap filling fluid reaction chamber, thereby at least partially filling the gap with a gap filling fluid, wherein the gap filling fluid comprises at least one of a metal and a metalloid;
moving the substrate into the transformation reaction chamber; and
subjecting the substrate to a transformation treatment in the transformation reaction chamber, thereby converting at least a part of the gap filling fluid into a transformed material.
